(19) United States
(12) Patent Application Publication
(10) Pub. No.: US 2010/0269879 A1
(43) Pub. Date: Oct. 28, 2010

(54) Low-cost quantum well thermoelectric egg-crate module

(76) Inventors: Fred Leavitt, San Diego, CA (US); Daniel Krommenhoek, Carls Bad, CA (US); Saeid Ghamaty, La Jolla, CA (US); Norbert Elsner, La Jolla, CA (US)

Correspondence Address: ROSS PATENT LAW OFFICE, P.O. BOX 2138, DEL MAR, CA, 92014, US

(21) Appl. No.: 12/460,424

(22) Filed: Jul. 17, 2009

Related U.S. Application Data
(63) Continuation-in-part of application No. 12/317,170, filed on Dec. 19, 2008.
(60) Provisional application No. 61/137,206, filed on Jul. 29, 2008.

(51) Int. Cl. H01L 35/30; H01L 35/34

(52) U.S. Cl. 136/205; 156/151; 136/201

(57) ABSTRACT

Quantum well thermoelectric modules and a low-cost method of mass producing the modules. The devices are comprised of n-legs and p-legs, each leg being comprised of layers of quantum well material in the form of very thin alternating layers. In the n-legs the alternating layers are layers of n-type semiconductor material and electrical insulating material. In the p-legs the alternating layers are layers of p-type semiconductor material and electrical insulating material. In preferred embodiments the layers, referred to as superlattice layers are about 4 nm to 20 nm thick. The layers of quantum well material is separated by much larger layers of thermal and electrical insulating material such that the volume of insulating material in each leg is at least 20 times larger than the volume of quantum well material.

### CROSS REFERENCE TO RELATED APPLICATIONS

The present invention claims the benefit of Provisional Patent Application, Ser. No. 61/137,206, filed Jul. 17, 2008 and is a continuation-in-part of Ser. No. 12/317,170 filed Dec. 19, 2008.

### FIELD OF THE INVENTION

The present invention relates to thermoelectric modules and in particular to such modules having very thin films.

### BACKGROUND OF THE INVENTION

Thermoelectric Materials

The Seebeck coefficient of a thermoelectric material is defined as the open circuit voltage produced between two points on a conductor, where a uniform temperature difference of 1 K exists between those points. The figure-of-merit Z of a thermoelectric material is defined as:

Z=α²/ρκ

where α is the Seebeck coefficient of the material, ρ is the electrical resistivity of the material and κ is the total thermal conductivity of the material. A dimensionless figure of merit is found by multiplying Z by an average temperature. Greater values of ZT indicate greater efficiency of the thermoelectric material.

A large number of semiconductor materials were being investigated by the late 1950's and early 1960's, several of which emerged with Z values significantly higher than similar values for metals or metal alloys. No single compound semiconductor evolved that exhibited a uniform high figure-of-merit over a wide temperature range, so research focused on developing materials with high figure-of-merit values over relatively narrow temperature ranges. Of the great number of materials investigated, those based on bismuth telluride, lead telluride and silicon-germanium alloys emerged as the best for operating in various temperature ranges. Much research has been done to improve the thermoelectric properties of the above three thermoelectric materials. For example n-type bismuth telluride, Bi₂Te₃ typically contains 5 to 15 mol percent Bi₂Se₃ and p-type Bi₂Te₃ typically contains 70-90 mol percent Sb₂Te₃. Lead telluride is typically doped with sodium for P type and iodine (PbI₂) for N type.

### Thermoelectric Modules

Electric power generating thermoelectric modules are well known. These modules typically are comprised of a number of thermoelectric elements called n-legs and p-legs connected electrically in series. The effect is that a voltage differential of a few millivolts is created in the presence of a temperature difference at the two junctions of p-type thermoelectric semiconductor elements and n-type thermoelectric semiconductor elements. Since the voltage differential is small, many of these elements (such as about 100 elements) are typically positioned in parallel between a hot surface and a cold surface and are connected electrically in series to produce potentials of a few volts. Electrons flow from the hot side to the cold side through the n-legs and from the cold side to the hot side through the p-legs. Many references refer to the current in the p-legs as holes flowing from the hot side to the cold side.

### Hi-Z Prior Art Bismuth Telluride Molded Egg-Crate Modules

For example Hi-Z Technology, Inc. offers a Model HZ-14 thermoelectric bismuth telluride thermoelectric module designed to produce about 14 watts at a load potential of 1.66 volts with a 200° C. temperature differential. Its open circuit potential is 3.5 volts. The module contains 49 n-legs and 49 p-legs connected electrically in series. It is a 0.5 cm thick square module with 6.27 cm sides. The legs are p-type and n-type bismuth telluride semiconductor legs and are positioned in an egg-crate type structure that insulates the legs from each other except where they are intentionally connected in series at the top and bottom surfaces of the module. That egg-crate structure which has spaces for 100 legs is described in U.S. Pat. No. 5,875,098 which is hereby incorporated herein by reference. The egg-crate is injection molded in a process described in detail in the patent. This egg-crate has greatly reduced the fabrication cost of these modules and improved performance for reasons explained in the patent. Insulating walls keep the electrons flowing in the desired series circuit. Other Bi₂Te₃ thermoelectric modules that are available at Hi-Z are designed to produce 2.5 watts, 9 watts, 14 watts and 20 watts at the 200° C. temperature differential. The term bismuth telluride is often used to refer to all combinations of Bi₂Te₃, Bi₂Se₃, Sb₂Te₃ and Sb₂Se₃. In this document where the term Bi₂Te₃ is used, it means any combination of Bi₂Te₃, Bi₂Se₃, Sb₂Te₃ and Sb₂Se₃.

### Temperature Limitations

The egg-crates for the above described Bi₂Te₃ modules are injection molded using a thermoplastic supplied by Dupont under the trade name “Zenite”. Zenite melts at a temperature of about 350° C. The ZT thermoelectric properties of Bi₂Te₃ peak at about 100° C. and are greatly reduced at about 250° C. For both of these reasons, use of these modules are limited to applications where the hot side temperatures are lower than about 250 ° C. to 300 ° C.

### Thermoelectric Efficiencies

Despite the fact that there exists a great need for non-polluting electric power and the facts that there exists a very wide variety of un-tapped heat sources, and the thermoelectric electricity would be free, thermoelectric electric power generation in the United States and other countries is minimal as compared to other sources of electric power. The reason primarily is that thermoelectric efficiencies are typically low compared to other technologies for electric power generation and the cost of thermoelectric systems per watt generated is high relative to other power generating sources. Generally the efficiencies of thermoelectric power generating systems are in the range of about 5 percent. Proposals to increase these efficiencies by stacking different types of materials have been made but these stacked designs become complicated and expensive to produce and the resulting efficiencies are not much better than about 10 percent.

### Attempts at Improved Performance

Workers in the thermoelectric industry have been attempting to improve performance of thermoelectric devices for the past 20-30 years with some success, but much more is needed. Most of the effort has been directed to reducing the thermal conductivity (κ) without adversely affecting the electrical conductivity. Experiments with superlattice quantum well materials have been underway for several years. These materials were discussed in a paper by Gottfried H. Dohler which was published in the November 1983 issue of Scientific American. This article presents an excellent discussion of the theory of enhanced electric conduction in super-lattices. These super-lattices contain alternating conducting and barrier layers and create quantum wells that improve electrical conductivity. These superlattice quantum well materials are crystals grown by depositing semiconductors in layers with thicknesses of about 10 nm (100 Angstroms). Thus, each layer may be less than 100 atoms thick. (These quantum well materials are also discussed in articles by Hicks, et al and Harman published in Proceedings of 1992 1st National Thermoelectric Cooler Conference Center for Night Vision & Electro Optics, U.S. Army, Fort Belvoir, Va. The articles project theoretically very high ZT values as the layers are made progressively thinner.) The idea being that these materials might provide very great increases in electric conductivity without adversely affecting Seebeck coefficient or the thermal conductivity.

The present inventors have actually demonstrated that high ZT values can definitely be achieved with Si/Si_{0.8}Ge_{0.2} super-lattice quantum well n-legs and p-legs (see U.S. Pat. Nos. 6,096,964 and 6,096,965). They have also demonstrated that these very high ZT values can be achieved with super-lattice modules having Si and SiC n-legs and B₄C and B₉C p-legs (see, for example U.S. Pat. No. 7,342,170). Most of the efforts to date with super-lattices have involved alloys that are known to be good thermoelectric materials for cooling, many of which are difficult to manufacture as super-lattices. The present inventors have had issued to them United States patents which disclose such materials and explain how to make them. These patents (which are hereby incorporated by reference herein) include U.S. Pat. Nos.: 5,436,467; 5,550,387; 6,096,964; 6,096,965; 7,038,234 and 7,342,170. The '234 patent describes n-legs utilizing Si and SiGe super-lattices and p-legs utilizing B₄C and B₉C super-lattices. The '170 patent discloses similar legs in which the n-legs utilize Si and SiC super-lattices with the p-legs also utilizing B₄C and B₉C super-lattices. A large number of very thin layers (in the '234 patent, more than 3 million layers per leg) together produce a thermoelectric leg about 0.4 cm thick. In the embodiment shown in the figures all the legs are connected electrically in series and otherwise are insulated from each other in an egg-crate type thermoelectric element as indicated in FIG. 3A. As shown in FIG. 3B electrons flow from the cold side to the hot side through p-legs and from the hot side to the cold side through n-legs. (Current is generally considered in most current thermoelectric texts to flow from cold to hot through the n-legs and holes flowing from hot to cold through the p-legs.)

For thermoelectric modules of the type described above in order to be generally competitive with other power generating methods must be made at costs in the range of about $1.00 per watt. The costs of prior art experimental device described above are many times this value.

What is needed is a method of making quantum well thermoelectric modules at costs of less than about $1.00 per watt.

### SUMMARY OF THE INVENTION

The present invention provides a quantum well thermoelectric module and a low cost method of mass producing the modules. The devices are comprised of n-legs and p-legs, each leg being comprised of layers of quantum well material in the form of very thin alternating layers. In the n-legs the alternating layers are layers of n-type semiconductor material and electrical insulating material. In the p-legs the alternating layers are layers of p-type semiconductor material and electrical insulating material. In preferred embodiments the layers, referred to as superlattice layers are about 4 nm to 20 nm thick. The layers of quantum well material is separated by much thicker layers of thermal and electrical insulating material such that the volume of insulating material in each leg is at least 12 times larger than the volume of quantum well material. In preferred embodiments the ratio is about 50 which results in a module cost of about $0.85 per watt. In preferred embodiments the quantum well material is produced with a sputter process in a web coater on an insulating substrate to produce quantum well film which is stacked with insulating spacers to produce a quantum well stack which is then sliced and diced to produce the quantum well legs.

Studies show that layers as thin as 4 nm may improve the thermoelectric properties through increased strain and improved quantum confinement. The low thermal conductivity substrates and spacers greatly reduce the thermal conductivity of the modules and greatly reduce the material cost of the modules.

### Web Coating Sputtering Machines

Superlattice quantum well material can be deposited with sputtering machines at a rate of about 10 nanometers per minute. A typical thermoelectric module designed in accordance with the present invention may contain only about 0.14 cm³ of the superlattice layer material. In prior art sputtering machines previously used by Applicants quantum well material could be produced at the rate of about 0.25 cm³ per day. Applicants have performed demonstration runs on a two-target web coating sputtering machine showing that with this prior art machine 1.4 cm³ of quantum well material could be produced per day, enough material per day for about 10 modules of a preferred module design. In addition Applicants have developed a preliminary design of a multiple target web coating machine to produce about 29 cm³ of super-lattice film per day, enough material to produce per day more than 200 modules of the preferred design.

### First Preferred Embodiment

In a first preferred embodiment 400 quantum well superlattice layers are grown on a 200 micron thick substrate in a web coating sputtering machine. The preferred substrate is Kapton coated with a 100 nm layer of crystalline silicon. Each superlattice layer comprises a 10 nm thermoelectric layer and a 10 nm insulating layer. The thickness of the quantum well material on the 200 micron thick substrate is about 8 microns, so the quantum well film is about 208 microns. This film is stacked 12 high with alternating layers of a 200 micron thick insulating spacer, so the stack of 12 quantum well films and 12 spacer films is about 0.49 cm thick. The stack of quantum well film and spacers are cut into legs with dimensions of about 0.3 cm×0.5 cm×0.49 cm. The legs treated with an ion implantation procedure and sputter coated at both hot and cold ends with molybdenum and silver to improve electrical connections between the legs and the legs are then assembled into a thermoelectric egg-crate similar to prior art thermoelectric egg-crates. The hot and cold surfaces of the egg-crates are spray coated with electrically conductive material preferably molybdenum followed by aluminum. Excess conductive material is then removed to expose the egg-crate walls so as to connect the legs in series and to produce a thermoelectric module rated at 46.8 watts with a 300° C. temperature difference. The ratio of insulating material to quantum well material in the legs is about 50. The estimated maximum efficiency of the module is about 21.4 percent. This preferred embodiment is a thermoelectric 10×10 egg crate type module about 5.55 cm×5.55 cm×0.7 cm. The module has 98 active thermoelectric legs, with each leg having more than 4,800 super-lattice layers. Applicants expect to be able to produce more than two hundred of these modules per day per web coating machine. Applicants expect to manufacture the modules for about $40 per module at a cost per watt of about $0.85/watt.

Applicants have designed similar egg-crate modules with more and less quantum well material in the legs. These include a 67.3 watt module (with an insulator to quantum well material ratio of about 12.6) which is expected to cost about three times as much pre watt as the 46.8 watt module but is expected to operate at a 3.5 percent increased in efficiency to about 24.9 percent. Modules with a larger than 50 insulator to quantum well material ratio could be substantially less expensive to produce but the output and efficiency will suffer when compared with the preferred module design.

### Other Superlattice Layers, substrates and Spacers In preferred embodiments the super-lattice layers are comprised of: SiGe and Si doped with phosphorous for the n-legs and SiGe and Si doped with boron for the p-legs. For high temperature operation silicon and silicon carbide super-lattice layers can be utilized. Depending on the cost of germanium, the substitution of SiC for SiGe could result in substantial cost reductions. Other thermoelectric super-lattice combinations could be used including all of those discussed in the background section. Preferred substrate film materials include Kapton, glass, silicon-coated glass and porous silicon. Substrates that can be dissolved (ie NaCl), evaporated or etched away (metals) can also be used. Also, for example, B₄C/B₉C can be substituted for p-type Si/Ge

### BRIEF DESCRIPTION OF THE DRAWINGS

FIG. 1 shows a high-cost, low volume process for making quantum well thermoelectric materials.

FIGS. 2A, 2B and 2C are views of sputter web coater adapted to produce quantum well thermoelectric film.

FIGS. 2D and 2E show alternative sputter machine designs.

FIGS. 3A and 3B show a prior art egg-crate and demonstrates series connection of the thermoelectric legs.

FIG. 4 shows a flow diagram for fabricating a preferred egg-crate thermoelectric module.

FIG. 4A show a section of a thermoelectric quantum well film with 800 quantum well layers on a 200 micron substrate.

FIG. 4B shows a section of a spacer for use with the FIG. 4A film.

FIGS. 4C and 4D show 25 cm² sections of the spacers and the quantum well film alternatingly stacked together.

FIG. 4E shows features of a quantum well in accordance with a preferred embodiment.

FIGS. 4F through 4J show magnified portions of the FIG. 4 leg.

FIG. 5 show details of five types of quantum well egg-crate designs.

FIGS. 6A, 6B and 6C show comparisons of quantum well model data and experimental data.

FIG. 7 shows predictions of the effect of strain on quantum well film.

FIG. 8 shows a mobius strip.

### DETAILED DESCRIPTION OF PREFERRED EMBODIMENTS

### Applicants Earlier Patents

On Aug. 1, 2000 Applicants were granted U.S. Pat. Nos. 6,096,964 and 6,096,965 both of which have been incorporated herein by reference. In these patents Applicants disclose techniques for placing the thin alternating layers on film substrates. In these patents the alternating layers specifically described include layers comprised of silicon and silicon-germanium. The Si layers are referred to as insulating or barrier layers and the SiGe layers are appropriately doped to produce n legs and p legs and are referred to as conducting layers.

An n-doping atom is typically the atom having one more electron in its valance layer than the base semiconductor atoms. An example is phosphorous (having five valence electrons). The n-doping phosphorous atom provides a conducting electron supporting hot side to cold side electron flow. A p-doping atom is typically the atom having one fewer valence electron than the base semiconductor atoms. An example is boron (having three valence electrons). The missing electron becomes an electron acceptor location (i.e., a hole) supporting cold side to hot side electron flow. Some materials are naturally n or p type materials without doping. As explained in the Dohler article, in these very thin layers electrons made available for electrical conduction in the n-doped conduction layer can migrate to the boundary layer to make conduction possible there. Applicants believe that the excellent electrical conducting properties of these materials are due to the fact that conduction can take place through the boundary layer crystals without being impeded by ions in the crystals which produce electromagnetic fields which are believed to impede the flow of electrons. The same reasoning applies to the p-doped layers. In this case excess electrons migrate from the boundary layers to the p-doped conduction layers to produce holes in the boundary layers without current impeding ions. Thus, resistance to current flow is enormously reduced. Some materials possess thermoelectric properties without doping. In the '387 patent Applicants disclose that the layers of boron-carbide would make very good thermoelectric material especially for the p-type legs. GeTe, PbTe and MnTe were also proposed as possible materials for the T/E elements.

### Applicants' Experiments

In 2002 Applicants produced a small test quantum well thermoelectric couple with 11 microns of Si/SiGe thermoelectric layers on a 5-micron silicon film that has operated at 14 percent conversion efficiency. This efficiency was calculated by dividing the power out of the couple by the power in to an electric heater with no correction for extraneous heat losses. The accuracy of the experimental set-up used was validated by measurement of the 5 percent efficiency of a couple fabricated of bulk Bi₂Te₃ alloys.

Measurements at University of California at San Diego on behalf of Applicants indicate that the thermal conductivity of the Si—SiGe multi-layer films are significantly reduced in comparison with the bulk value. The use of the UCSD low value for the in-plane thermal conductivity leads to a factor of three enhancement in the performance (i.e., figure of merit) of the material. Table 1 includes Applicants' latest estimates of electrical properties of Si/SiC and Si/SiGe quantum well materials.

### Applicants' Demonstration Projects

Applicants have successfully produced Si/SiGe, B₄C/B₉C and Si/SiC multi-layer quantum well films. Magnetron sputtering was used to deposit films with Si as the barrier material, on silicon and Kapton substrates. Films of individual layer with various thicknesses were deposited. Measurements on these materials indicated excellent resistivity and Seebeck coefficient values. Table 1 shows the thermoelectric properties of these films at room and higher temperatures. These numbers confirm the promise of these material combinations, resulting from QW confinement of the carriers. Based on thermal conductivity measurements of Si/SiGe and B₄C/B₉C films, which have a factor of 3-4 reduction versus bulk alloys, multi-layer QW Si/SiC films are expected on theoretical grounds to show similar reductions in thermal conductivity.

TABLE 1
Electrical Properties of Some QW Materials

| | Si/SiC | | | Si/SiGe | | | | B₄C/B₉C | | |
|---|---|---|---|---|---|---|---|---|---|---|
| temp | α | ρ | pwr | α | ρ | pwr | α | α | ρ | pwr |
| (° C.) | (μV/K) | (mΩcm) | (mW/cmK²) | (μV/K) | (mΩcm) | (mW/cm) | (mW/cmK²) | (μV/K) | (mΩcm) | (mW/cmK²) |
| 25 | 1,200 | 0.95 | 1.5 | 1,000 | 1.00 | 4.5 | 1.0 | 1,000 | 1.10 | 0.91 |
| 250 | 1,300 | 0.55 | 3.1 | 1,200 | 2.60 | — | 0.55 | 1,050 | 0.45 | 2.45 |
| 500 | 1,500 | 0.39 | 5.8 | 1,250 | ~4.00 | — | 0.39 | 1,100 | ~0.25 | ~4.84 |

### Fabrication of Quantum Well Thermoelectric Film

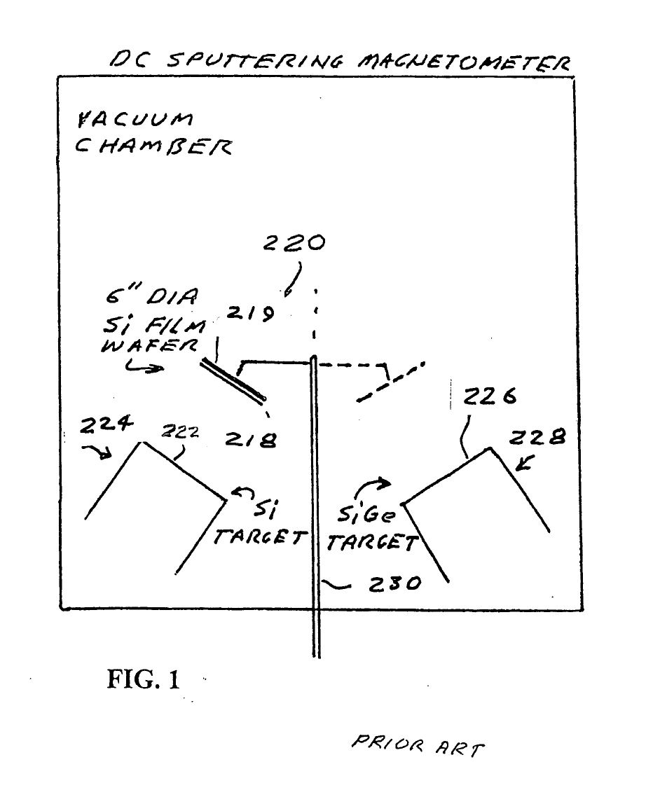

FIG. 1 is a prior art drawing of the primary elements of a DC sputtering magnetometer set up to produce Si/SiGe thermoelectric film. A 5-micron thick n-doped silicon wafer which functions as a silicon substrate 218 is placed on a graphite holder 219 as shown at 220 in FIG. 1. A Silicon target 222 is placed on high voltage target holder 224 and a SiGe target 226 is placed on high voltage target holder 228. The targets are maintained at 800 volts with a current of about 0.1 amps. The sputtering chamber is a brought to a vacuum of about 15-20 microns of Hg with a pure argon environment. Argon ions bombard the targets releasing target atoms from target 222 that collect on the substrate 218. The substrate 218 was maintained at a temperature of about 375 degrees C. to help balance out stresses that otherwise tend to develop in the deposited film. The sputtering magnetometer is operated so as to deposit 10 nm (0.01 micron) layers on substrate 218 at the rate of about one layer per minute. After the first silicon layer is deposited, substrate holder is pivoted so that substrate 218 is positioned over SiGe target 226 and a 10 nm layer of SiGe is deposited on top of the 10 nm silicon layer. This process is repeated until a desired number of layers are produced. That system produced thousands of super lattice-layers but the film area was only about 175 square cm. At a rate of 10 nm per minute a volume of thermoelectric material about 0.25 cm³ could be produced per day which is enough material for about one module in accordance with a typical thermoelectric module fabricated in accordance with the first preferred embodiment of the present invention. This prior art technique has also been used to produce silicon carbide quantum well film merely by using a SiC target instead of the Si₈₀Ge₂₀ target. And it has been used to produce B₄C/B₉C legs by replacing the Si targets with B₄C targets and the SiGe targets with B₉C targets.

### Very Large Area Super-Lattice Films

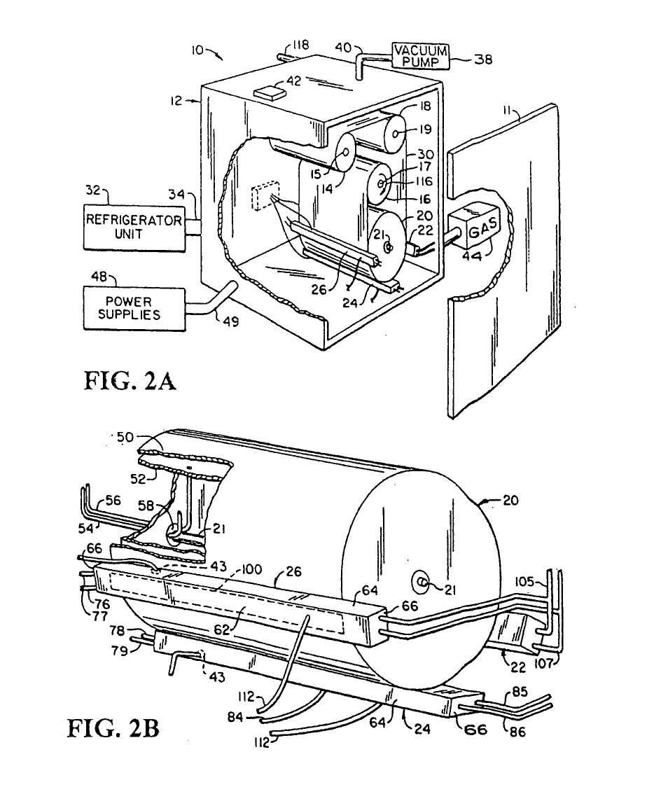

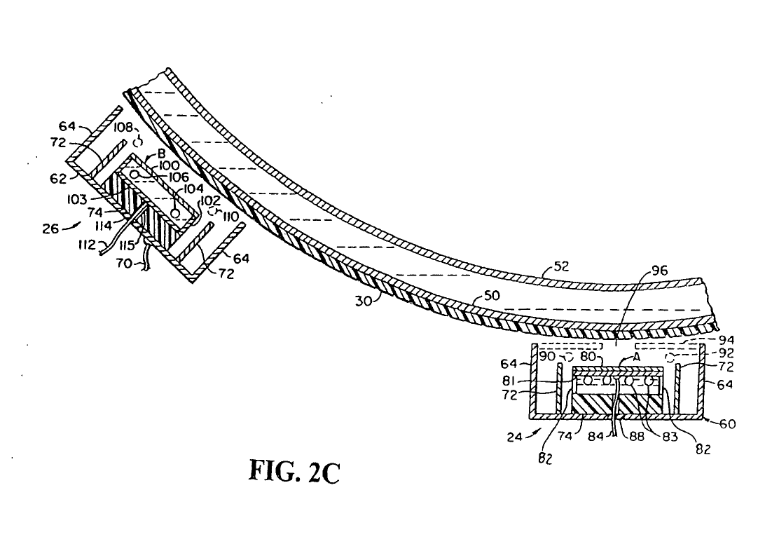

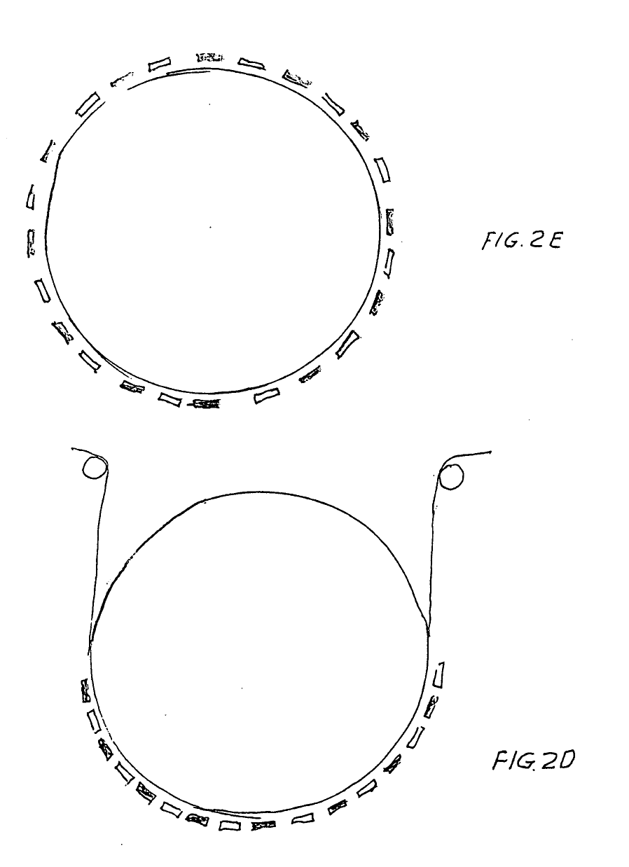

Applicants have now actually demonstrated that with an existing large web coater type sputtering machine similar to the one shown in FIGS. 2A, 2B and 2C with only two sputter targets, each 1 meter (100 cm)×5 cm, quantum well material could be deposited at 10 nm per minute. This machine can produce quantum well film volume at a rate of 1.44 cm³ of quantum well material per day. The quantity of thermoelectric material required per module depends on the module design. A preferred design is described in the section below entitled “First Preferred Thermoelectric Module”. This module requires 0.144 cm³ of quantum well material, so the machine described above can produce enough quantum well material for about 10 of these modules per day.

The equipment used was a web coater sputtering machine of the type described in U.S. Pat. No. 4,204,942. FIGS. 2A and 2B are drawings FIGS. 1 and 2 from that patent which is incorporated herein by reference. This web coater sputtering machine comprises three deposition chambers only two of which were used to deposit the super-lattice layers on the substrate film. Each chamber may be provided with a target material to be sputtered onto the substrate. Details of the web coater extracted from the '942 patent are described in the next section. Various procedures for controlling the depositions are described below. In the section Many Target Sputter Machines Applicants have proposed designs for sputter machines with up to forty 500 cm² targets that would increase the quantum well film production by a factor of 20 so that quantum well film for 200 of the typical modules could be produced per day with a single machine.

### Description of Prior Art Web Coater

FIG. 2A illustrates a preferred prior art web coater. The apparatus, generally designated by the reference numeral 10, includes an evacuable chamber 12 with door 11 removed to show mounted interior of the chamber play-out roll 14, take-up roll 16, idler drum 18 and support cylinder 20. The film is fed from play-out roll 14 onto idler drum 18 and taken up on take-up roll 16. The play-out and take-up rolls, as well as idler drum 18, are rotatably mounted to a portion of the chamber 12 via spindles 15, 17 and 19, respectively. Similarly, support cylinder 20 is rotatably mounted to spindle 21. The spindles 15, 17, 19 and 21 are generally horizontally oriented and parallel to one another. Also mounted within the chamber at spaced locations about the outer circumferential surface of the support cylinder 20 are deposition stations 22, 24 and 26.

As illustrated in FIG. 2A, a substrate 30 (typically a long, thin sheet of Kapton) is mounted upon play-out roll 14 and then caused to extend from the play-out roll to take-up roll 16 via idler drum 18 and support cylinder 20, passing through (as will be more particularly shown below) the interstitial space between deposition stations 22, 24 and 26 and support cylinder 20.

Apparatus 10 further includes a refrigeration unit 32 which is communicated to the chamber 12 via a conduit 34 to provide the support cylinder 20 and deposition stations 22-26 with a coolant. For clarity, conduits communicating the coolant to the individual deposition stations are not fully illustrated in the Figures.

A vacuum pump 38 is communicated to chamber 12 via exhaust conduit 40. With chamber door 11 securely attached to chamber 12 so that it hermetically seals the chamber, the pump 38 can partially evacuate the chamber to pressures of 1 millitorr. Sensor 42 is provided to monitor the chamber pressure.

A gas supply unit 44 communicates an admixture of reactive gas to stations 22 and 26 to provide a reactive sputtering process. Similarly, gas supply unit 44 supplies an inert or nonreactive gas to deposition station 24 for generating the gas-discharge plasma that will provide the sputtering environment for that station. In addition, each deposition station 22, 24, 26 is provided with a separate source of electrical power to control the sputtering taking place at each station. Accordingly, there is provided power supplies 48 to supply the corresponding deposition stations with the appropriate high voltage required for the sputtering process. Again for clarity, the conduits and electrical lines which communicate the gases and electrical power to each deposition station are not fully illustrated in the Figures.

Referring now to FIG. 2B, it can be seen that support cylinder 20 includes an outer cylindrical jacket 50 and an inner cylindrical jacket 52. The outer and inner jackets 50 and 52 relatively situated concentric to each other are dimensioned so that a space is formed between the two jackets. Both outer and inner jackets 50 and 52, respectively, are formed from hot rolled steel. Additionally, the outer surface of jacket 50 (and, therefore, support cylinder 20) is provided with a polished, hard chrome coating.

Inlet and outlet coolant lines 54 and 56, respectively, carry a coolant to and from the support cylinder. The lines 54, 56 pass through a rotating coaxial seal 58 of known construction to communicate water (cooled to about 22.degree. C.) to and from the interstitial area between jackets 50 and 52 of support member 20, thereby cooling the support cylinder.

Referring now to both FIGS. 2B and 2C, the deposition stations 22, 24 and 26 can now be described. At the outset, it will be noted that the structure of all three stations is essentially the same. Accordingly, the same part numbers will be used to designate those elements which are identical, while structural differences will be noted and given different reference numerals as appropriate. Further, deposition stations 22 and 26 are in all respects identical and, therefore, only deposition station 26 is illustrated in FIG. 2C. Therefore, any discussion of the structural and functional aspects of deposition station 26 will apply equally to deposition station 22 and 24.

Accordingly, as illustrated in FIGS. 2B and 2C, deposition stations 22, 24 and 26 are elongated structures arranged at spaced locations about circumferential surface of support cylinder 20. Each deposition station is oriented with its longitudinal dimension generally parallel to the axis of support cylinder 20. Each deposition station includes a box-like housing 60 that is formed from a base wall 62, side walls 64, and end walls 66. Side and end walls terminate to define an opening that is positioned in spaced, confronting relation with the circumferential surface of support cylinder 20. Each housing 60 has electrically coupled thereto a ground lead 43 which electrically communicates the housing 60 to an electrical common (not shown). The outer and inner jackets 50 and 52, respectively, of support cylinder 20 are also electrically coupled to this common.

Mounted interior of housing 60 and extending generally parallel to side walls 64 are side shields 72, which act to quench plasma at the side walls of the cathode structures A and B of deposition stations 24 and 26, respectively, and thereby inhibit side sputtering. Affixed to base wall 62 of each housing 60 is a cathode mount 74, which is fabricated from a material having high insulating qualities.

The cathode structure A of deposition station 24 includes a long planar target 80 of conductive metal that is soldered or otherwise securely (and electrically) attached to a copper target support plate 81. In turn, support plate 81 is mounted to cathode mount 74 via stands 82, which are affixed to the mount 74 so that the target, target support plate, and stands are electrically isolated from the housing 60. Coolant tubing 83 is attached to the target support plate 81 for extracting heat from the support plate and target 80 attached thereto when a coolant is passed through the tubing. Inlet and outlet lines 78 and 79 communicate a coolant (typically water) to tubing 83 in such a manner so as to keep a flow continuing the rethrough. Additionally, attachment of the coolant lies 78, 79 to the tubing 83 is made via appropriate insulation devices (not shown) so that any electrical shorts of the high voltage to ground are avoided. A high-voltage lead 84 is electrically secured to support plate 81 to electrically communicate the support plate and target to the corresponding one of power supplies 48.

The cathode structures B of deposition stations 22 and 26 are constructed in a similar fashion. A target 100, fabricated from a reactive metal (e.g., one that will react with the gas supplied for plasma generation to produce a deposit having the qualities of an insulator) is attached to cathode mount 74 by support member 102 in such a way as to isolate the target and support member from the housing 60. A bottom plate 103 overlays cathode mount 74. Target 100, support member 102 and bottom plate 103 are constructed so that they are all electrically one element and are configured to form an elongate, water-tight reservoir into which coolant (again, typically water) may be introduced via inlet port 104 to cool the target. Egress is provided by outlet port 106. The coolant is communicated between refrigeration unit 32 and deposition station 26 (and 22) by coolant lines 76, 77, the coolant lines being attached to ports 104, 106 via appropriate insulating apparatus (not shown) so that electrical isolation of the target 100 from housing 60 is maintained.

A high-voltage lead 112 is electrically attached to bottom plate 103 (and, therefore, target 100) to electrically communicate the target to its corresponding one of power supplies 48. As indicated in FIG. 2C, high-voltage lead 112 passes through housing 60, via an insulating grommet 114 situated in an aperture in housing 60 and bore 115 formed in cathode mount 74.

In operation, a cylindrical roll of a long strip of plastic substrate (typically Kapton) is mounted to spindle 15, forming play-out roll 14. A portion of the substrate is played out so that it extends along a path that is around idler drum 18, support cylinder 20 (through the interstitial spacings between the deposition stations and support member), terminating at take-up roll 16. With the substrate 30 so positioned (as illustrated in FIG. 2A) door 11 is attached to chamber 12, hermetically sealing the interior of the chamber. Vacuum pump 38 begins to evacuate chamber 12 until an interior pressure of approximately two millitorr is reached. At this time, gas supply unit 44 begins supplying an admixture of a reactive gas to deposition stations 22 and 26, via gas lines 105, 107, in sufficient quantity to establish and maintain a pressure of 11 millitorr within the housings 60 of the deposition stations. Similarly, the gas supply unit 44 provides deposition station 24 with a flow of non-reactive gas via gas lines 85, 86, which is introduced into housing 60 of deposition 24 via inlet 90 and evacuated via outlet port 92. The flow of the non-reactive gas introduced into housing 60 of deposition station 22 should be sufficient to maintain the pressure therein also at approximately 11 millitorr.

A negative high-voltage potential of approximately 500 volts at 10 amps is supplied by the corresponding ones of power supplies 48 to the targets 100 of deposition stations 22 and 26; at the same time, a negative high voltage of approximately 400 volts at 2.5 amps is applied to target 80 of deposition station 24. At the same time, take-up roll 16 is caused to begin revolving in the direction of arrow 116 by motor means 118 which is coupled to the take-up roll via an appropriate drive mechanism (not shown) such as a continuous belt. As take-up roll 16 rotates, substrate 30 is played out from play-out roll 15 and across support cylinder 20 so that the substrate continuously passes proximate each deposition station. Thereby, the substrate is first caused to have deposited a layer of insulation (the product of sputtering a reactive metal in the admixture of reactive gas provided deposition station 22).

The rate at which substrate 30 is moved by the respective deposition stations is a function of the type of sputtering conducted and the coatings desired. However, under the conditions of voltages and gases set forth above, it is presently preferred that substrate 30 move at a rate of approximately nine inches per minute past the respective deposition stations.

In addition, it is well known that the sputtering process tends to heat the substrate. To avoid melting or otherwise damaging substrate 30, support cylinder 20 is constructed, as described above, to remove thermal energy from the substrate during the sputtering process. However, to ensure good thermal conductivity between the outer surface of the support cylinder and substrate, play-out roll 14 and/or idler drum 18 are preferably constructed with a predetermined amount of drag that works against the pull on the substrate by take-up roll 17 (and its associated motor 118). This drag will act to tension the substrate against support cylinder 20, thereby establishing good thermal contact there between. The amount of such drag is a matter of choice which can vary depending upon the particular substrate which is to be coated. Moreover, creation of such drag can be by way of any one of several known methods—such as controlling the friction engagement of play-out roll 14 and idler drum 18 on their respective spindles 15 and 19.

### Making the Super Lattice Film

In the preferred embodiment, high volume quantum well multi-layer films are fabricated on a large area web coater sputtering machine with specific ion beam, laser assist, substrate preparation, substrate heating, pulse power supply, deposition rate, lithographically patterned electrical contacts and deposition of metal contacts on large area quantum well films for quantum well module high volume fabrication.

Alternating layers of Si_{0.8}Ge_{0.2} and Si were grown on Kapton® and Mylar® substrates from two targets in a magnetron sputtering system with the web coater. The plasma, web speed, pulse power frequency, pulse duration and power were set to yield a deposition rate of 10 nm/min and 50 alternate Si_{0.8}Ge_{0.2} layers of 10 nm and individual alternating layers of Si each 10 nm to give a total thickness of 1 micron. Prior to deposition, Kapton® and Mylar® substrates were cleaned and a 50 nm thick Si buffer layer was applied to the Kapton® and Mylar® substrates by magnetron sputtering in a web coater. A thin 300 μm thick Si substrate also was used to demonstrate use of a crystalline substrate for web coating. The pulse power supply operated at a frequency of 15 kHz and a pulse width of 2.2 μsec for both the Si_{0.8}Ge_{0.2} and Si source targets. The Si_{0.8}Ge_{0.2} source targets power was 3,000 Watts at a belt speed of 3.6 ft/min and the Si source target's power was 3,000 Watts at a belt speed of 2.5 ft/min.

The actual deposition configuration is illustrated schematically in FIG. 2A. A supply roll 14 has Kapton substrate 30 which travels past a bow roller 19 and drum 20 and tensioner 18 and take-up roll 16. The supply roll 14, bow roller 19, drum 20, tensioner 18 and take-up roll 16 rotate in both clockwise and counterclockwise directions to permit substrate 30 to first pass in front of Si_{0.8}Ge_{0.2} target 100 to deposit 10 nm at 10 nm/min of Si_{0.8}Ge_{0.2} and then pass in front of target 6 to deposit 10 nm at 10 nm/min of Si. Double sided deposition of Quantum Well thermoelectric has been made by turning the film over and depositing alternate layers of Si_{0.8}Ge_{0.2} and Si as described above. The supply roll and take-up roll provide axial tension along the length of substrate film and the tensioner provides additional axial tension along the length of the substrate. The bow roller 8 provides tension in both the axial direction and at 90° to the axial direction. Quantum Well thermoelectric films have been formed by DC power sputtering, pulse power sputtering with continuous power to both source targets, and with power to only one source target at a time.

In preferred embodiments the deposition target source 6 is pure Si and deposition target source 5 is Si₈₀Ge₂₀ doped to ˜10¹⁹ phosphorous carriers per cc for n-type film. For P type film, boron was used as the dopant also at ˜10¹⁹ atoms per cc. Antimony could also be used as the N type dopant. The sputtering should be operated using an argon pressure between 0.001 and 0.1 torr. During deposition of films, the substrate should be about five centimeters from the sputtering targets. Preferred processes utilize two 5 kW pulse power magnetrons, one having a source target of Si_{0.8}Ge_{0.2} that is 5 cm×100 cm with a 0.375 cm thickness, and the other having a source target of Si with the same sizes. Substrate 3 on supply roll 2 could be about 1 meter wide×300 meters long. Many other supply roll substrate materials are possible.

Substrates and films can be heated and cooled prior to deposition, during deposition and subsequent to deposition as a means to control structure of individual layers of crystalline films. FIG. 2B shows the central drum with an internal substrate temperature controlled heater 40. This heater provides substrate temperatures of 325° C. for Kapton and 500° C. for Si substrates. Ion beam assisted deposition 43 may be applied prior to deposition on the substrate and post deposition to anneal the thin films. A laser operating in a range from UV to IR energies may be used to promote crystal growth of thin films. Bow roller 19 and tensioner 18 maintain substrate in tension both perpendicular to length and along length of long substrates.

### High Volume Sputter Machines

As explained above the prior art web coater can produce enough quantum well material per day for about 10 modules of a preferred design. Applicants have developed preliminary designs for high volume sputter machines for greatly increasing production rates of the quantum well film. An important limiting factor in quantum well film production is that the quality of the film decreases substantially if the deposition rate exceeds about 10 nm per minute. The area of the substrate covered by deposition is approximately equal to the effective area of the targets. Therefore, to increase the production rate the target area should be increased. This can be accomplished by increasing the number of targets or increasing the size of the targets. FIG. 2D shows a proposed design with 16 targets (8 Si and 8 Si₈₀Ge₂₀). The targets are just like the ones described above for the two-target machine, each one meter long and 5 cm wide other specifications are also the same or similar. With this machine the production rate of quantum well film could be increased by a factor of eight from the two-target machine described above from 1.44 cm³ per day to about 11.5 cm³ per day (enough for 48 modules per machine per day). FIG. 2E is a similar design except in this case the substrate film (having a length approximately equal to the circumference of the drum is mounted on a large 4-meter diameter cylindrical drum and targets are spaced entirely around the drum. In the drawing shown, 24 targets are provided which, assuming the same size targets as in the two-target embodiment described above, would provide for a factor or 12 improvement in the film production rate resulting in a daily production rate of about 72 modules per day per sputter machine. Applicants have also proposed a larger machine with forty 5 cm×100 cm targets to provide a factor of 20 improvement in the production rate which would result in a production per machine of 28.8 cm3 per day. This is enough quantum well material for 120 modules of the type 3 preferred design. If we assume a cost of about $2,000 per 24-hour operation of the machine, the estimated cost of the quantum well material would be roughly $70/cm³.

### Preferred Egg-Crate Module Design

A preferred thermoelectric module is an egg-crate type module approximately 5.55 cm×5.55 cm square and 0.7 cm thick. The module consists of a 10×10 matrix of thermoelectric elements with each element being an approximate cube about 5 mm×4.9 mm square and about 3 mm thick. Forty nine of the thermoelectric elements are P type conductors and forty nine are N type conductors and they are connected in such a way that they are electrically in series but thermally in parallel. Two of the corners are used to fasten power leads and so do not contain thermoelectric elements. The electrical connectors are formed by thermally spraying molybdenum and aluminum (or silver) metal as described in Applicants' employer's prior art U.S. Pat. No. 5,875,098 (see FIGS. 19A and 19B and related text). The fabrication of the egg-crate is also described in the '098 patent.

Each thermoelectric element consists of twelve layers of quantum well films with a spacer layer of Kapton film in between each quantum well film layer. The Kapton film serves two purposes; it bonds the layers together and also acts as a thermal insulator to reduce the heat flux. Reducing the heat flux permits the use of fewer elements that are shorter. This means that less quantum well material is required resulting in a significantly lower cost with only a small sacrifice in efficiency due to some bypass heat loss through the Kapton.

The quantum well film for this module and the process for making it is described above. A preferred quantum well film is comprised of a Kapton substrate that is 200 μm thick and 400 alternating layers of silicon and silicon germanium deposited on one surface of the Kapton substrate. The thickness of each layer of silicon is 10 nm and each layer of SiGe is also 10 nm. The total thickness of the 800 layers is about 8,000 nm or 8 microns so the quantum well film including its substrate is about 208 microns thick. A step-by-step procedure for making the egg-crate module is described in the section below.

### Preferred Procedure for Fabricating the Egg-Crate Module

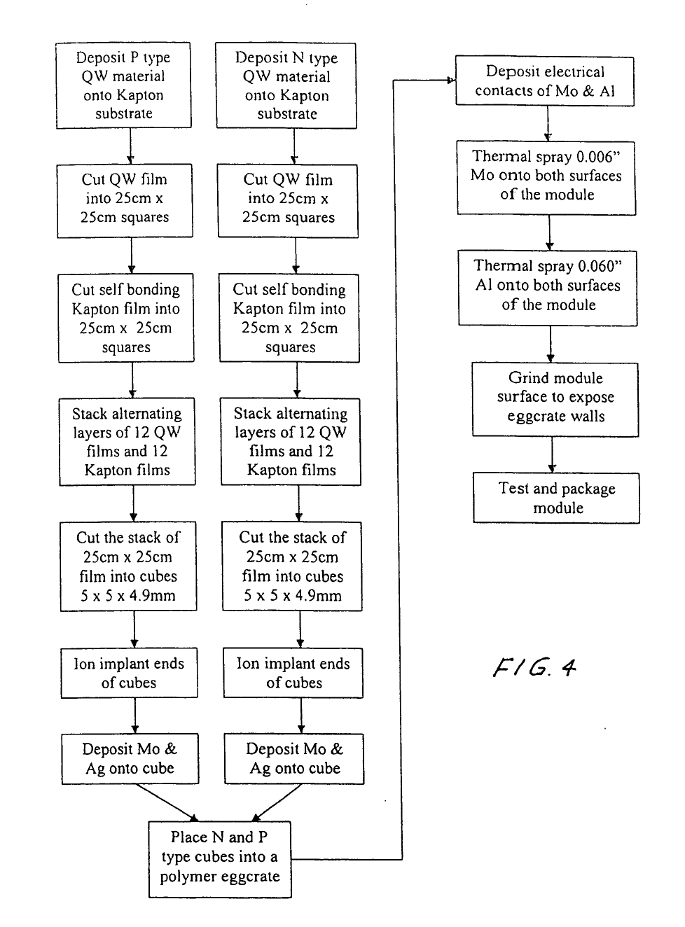

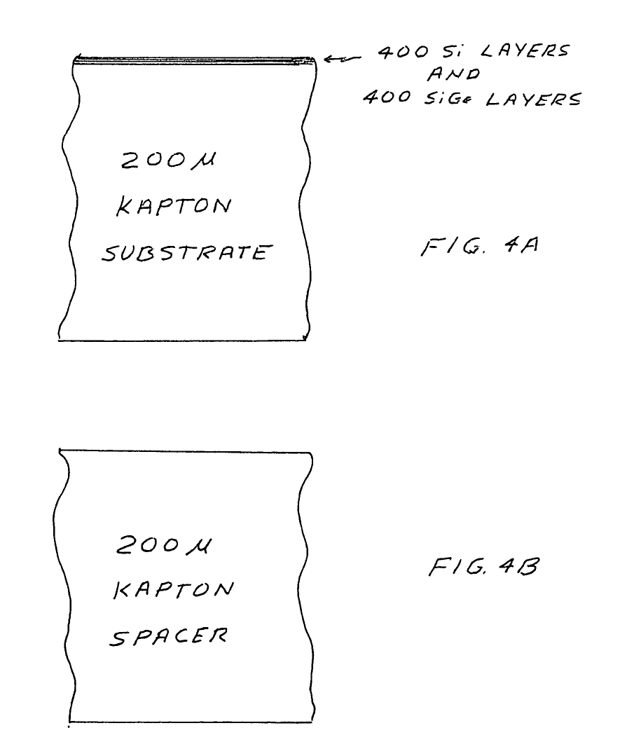

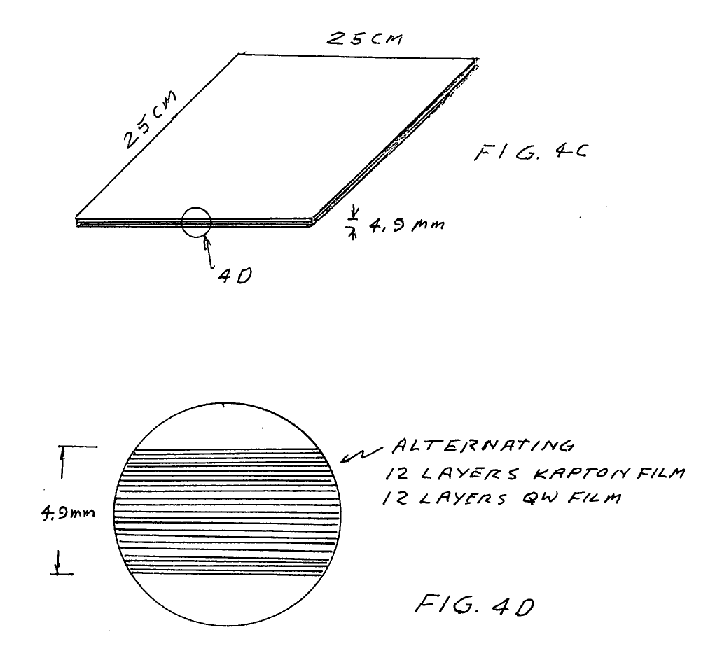

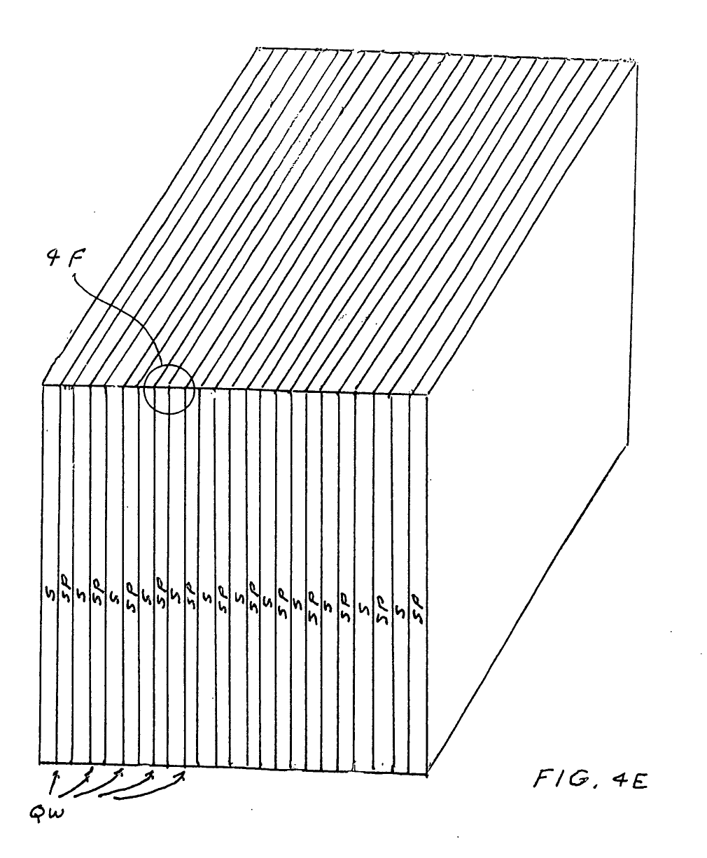

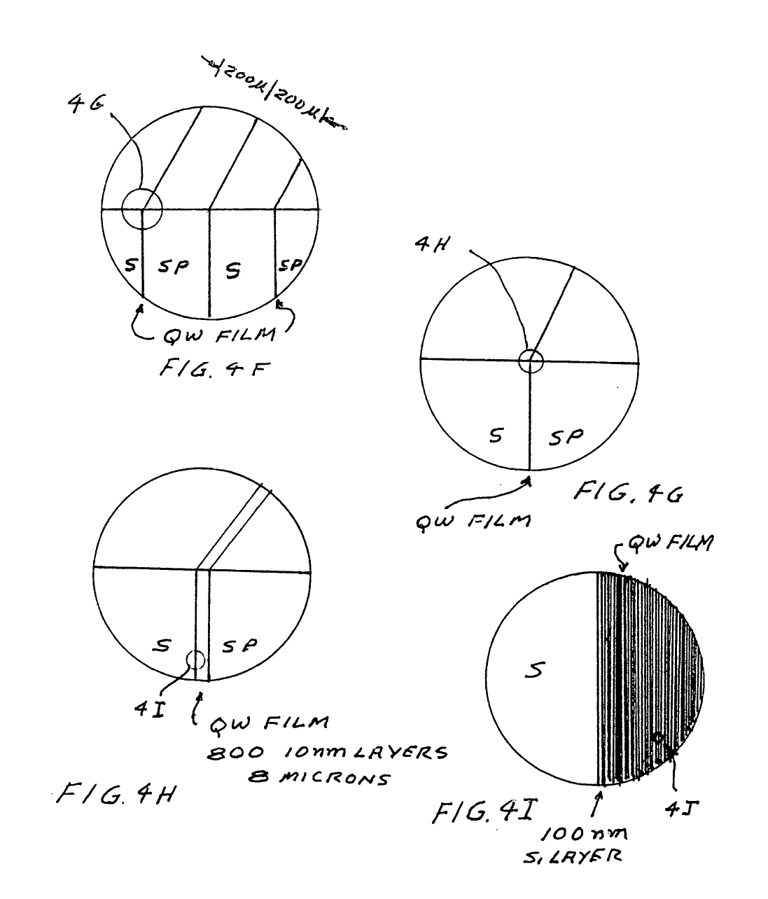

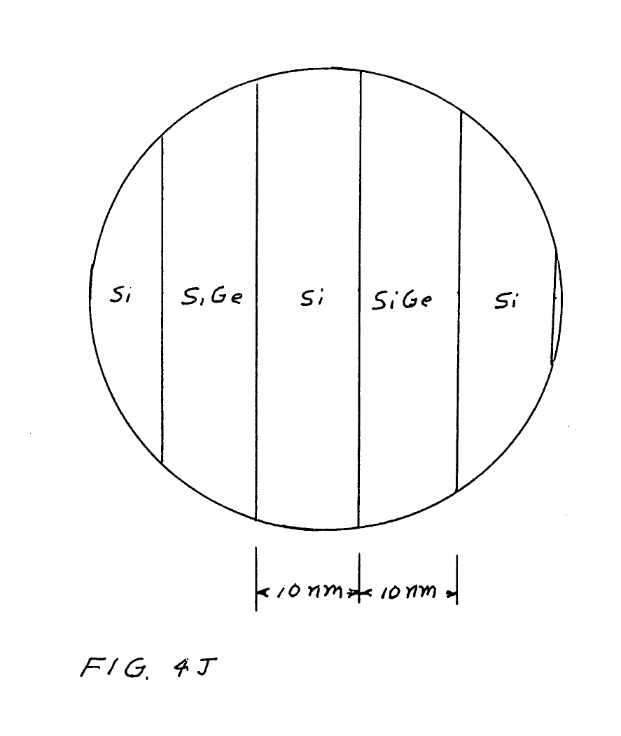

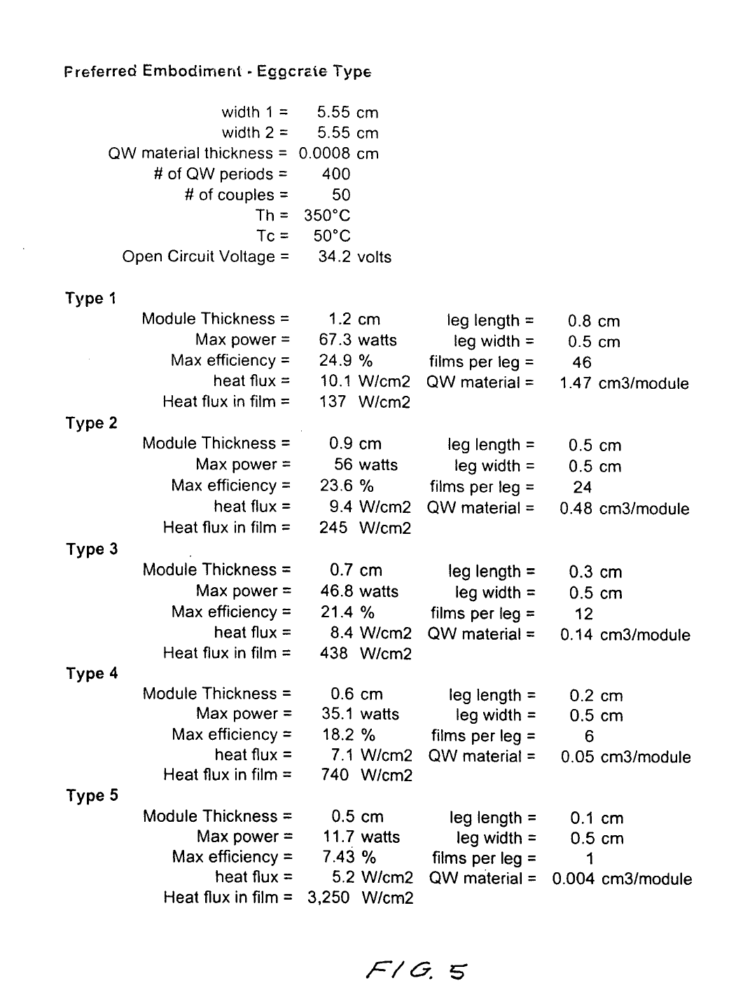

FIG. 4 is a flow chart describing the fabrication of the preferred embodiment. The fabrication process is also described in the text below.
1) Prepare quantum well film as described above. The preferred embodiment uses Si for the barrier layer and SiGe for the quantum well layer. The quantum well film for this module and the process for making it is described in general above. For this embodiment, each film layer comprises a Kapton substrate that is 200 μm thick and 400 alternating layers of silicon and silicon germanium deposited on one surface of the Kapton. The thickness of each layer of silicon is 10 nm and each layer of SiGe is also 10 nm. The total thickness of the 800 layers is about 8,000 nm or 8 microns so the quantum well film is about 208 microns thick. A cross section of a single quantum well film with the 800 quantum well layers (400 quantum well periods) is shown in FIG. 4A. About 300 cm³ of the quantum well film (150 cm3 of p-type and 150 cm3 of n-type) is needed for a typical 100 leg thermoelectric module. (The first layer on the Kapton film should be Si and in preferred embodiments this first layer could be significantly thicker than 10 nm, for example a 100 nm first Si layer is recommended.)
2) Cut the quantum well film into 25 cm×25 cm sections and cut an equivalent number of 200 micron thick Kapton film depicted in FIG. 4D into 25 cm×25 cm sections to function as spacer films between the quantum well films.
3) Stack twelve quantum well films and twelve Kapton films alternately on top of each other. The top layer of the stack is a Kapton spacer and the bottom layer is a Kapton substrate. These top and bottom layers of Kapton will help to protect the quantum well layers from damage. The stack of 25 cm×25 cm films is shown in FIG. 4C. A cross section of the stack is shown in FIG. 4D.
4) The Kapton spacers are self bonding films that can be bonded by heating at 350° C. for one hour while holding the stack under compression. Once the stack of twelve QW films and twelve Kapton spacers are fully bonded the resultant stack up will be about 4.9 mm thick.
5) Cut the stack of QW films into blocks that are 3 mm×5 mm square. This will result in cubes that are 3 mm×5 mm×4.9 mm. An excimer laser has been shown to be effective at cutting quantum well films.
6) Fasten the p-type legs into a fixture and ion implant one of the 4.9 mm×5 mm surfaces of the legs with boron ions. The boron ions are implanted to a depth of 112 nm and then to a depth of 77 nm and then finally 40 nm. Implanting boron ions into the surface of the leg dopes the semi conducting materials making them more electrically conductive to provide a low contact resistance when the leg is bonded to a metal conductor as described below.
7) Step 6 is repeated on the surfaces of the legs that are opposite the surface that was implanted in step 6.
8) Steps 6 and 7 are repeated for the n-type legs except phosphorous ions are implanted to depths of 43 nm, 30 nm and 17 nm.
9) The surfaces that were ion implanted are sputter coated with a 5 μm thick layer of molybdenum, or MoSi₂, and then a 5 μm thick layer of silver. The silver is a soft compliant material and can yield to reduce strain due to thermal cycling and then anneal at a temperature of 300° C.
10) The coated surfaces of the legs are then annealed at 900° C. for ten seconds. The surface must be rapidly annealed to prevent damage to the Kapton spacers and substrates in the bulk of the leg. Annealing the leg ends allows the implanted dopant to diffuse into a stable location in the leg matrix where it can function properly plus the high temperature allows the molybdenum, or MoSi₂, to react briefly with the silicon to form a thin layer of MoSi₂. Since MoSi₂ has a band gap closer to that of the silicon it forms a low energy barrier resulting in a lower contact resistance.
11) Fabricate a liquid crystal polymer eggcrate as described in U.S. Pat. No. 5,875,098. This eggcrate is designed to hold 49 P type legs and 49 N type legs in a 10×10 matrix. Two corner positions that would normally hold a leg are used to attach electrical contacts leaving 98 positions that can hold thermoelectric legs.
12) Load the n-legs and p-legs into the egg-crate and connect them electrically in series using the metal thermal spray technique described in the '098 patent in the section entitled “PROVIDING ELECTRICAL CONNECTIONS FOR THERMOELECTRIC ELEMENTS” and FIGS. 19A and 19B of that patent. Complete the fabrication of the module as described in the '098 patent.

When thermoelectric modules are fabricated in high volumes, following the ten steps previous described, the fabrication costs of these modules should be about $30 per module. When operated at a hot side temperature of 350° C. and a cold side temperature of 50° C., this module will produce more than 46.8 watts of electrical power for a cost per watt of less than $0.65. The efficiency of the module is expected to be about 21.4 percent.

### Fabrication Cost Per Module

The major cost of the thermoelectric module described above is expected to be the cost of the quantum well material. The volume of quantum well material in the preferred type 3 egg-crate module is 0.144 cm³/module. (The quantum well thickness is 0.0008 cm. The film area per film in each leg is 0.5 cm×0.3 cm or 0.15 cm². So the volume of quantum well material per film in each leg is 0.0001 cm³. The number of films per leg in the preferred embodiment is 12 so the volume of quantum well material per leg is about 0.0014 cm³. There are approximately 100 legs per module so the volume of quantum well material per module is about 0.144 cm³.) With an estimate of $70/cm3 for the cost of the quantum well material, the quantum well material in the preferred embodiment would be about $10.00 This $10.00 is similar to the cost of the material used in the fourteen watt bismuth telluride module currently being marketed by the Applicants' employer but the quantum well module will generate more than 46 watts of power.

### Other Egg-Crate Designs

The reader will note that according to the above description, the amount of quantum well material in each module is very small compared to the substrate and spacer material. There are many advantages associated with the relatively small volume of quantum well material compared to the spacer and substrate material. The main advantage is cost. The quantum well material cost is many orders of magnitude greater than the substrate and spacer material when figured on a volume basis. A second advantage is the thermal conductivity of the substrate and spacer material is orders of magnitude lower on a volume basis than that of the quantum well material. This has the effect of reducing greatly the thermal flux through the thermoelectric module. The down-side of reducing the relative amount of quantum well material in the thermoelectric legs is that ideally most of the thermal energy must pass through the quantum well layers. When the area of the quantum well layer is too small compared to the area of the leg, then the heat flux becomes too high and the desired temperature difference can not be achieved. This means that there is a practical lower limit on the amount of quantum well material needed in a module that will depend in large part on the specific application. Use of the spacers and the inclusion of the insulating substrates in the design of the modules as indicated in FIG. 5 also reduce somewhat the power output and the module efficiency.

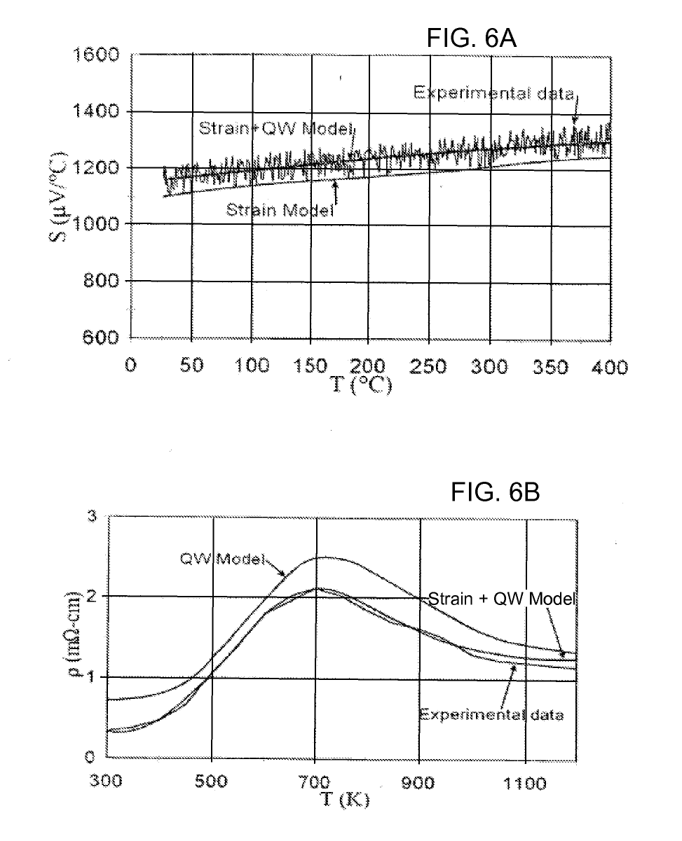

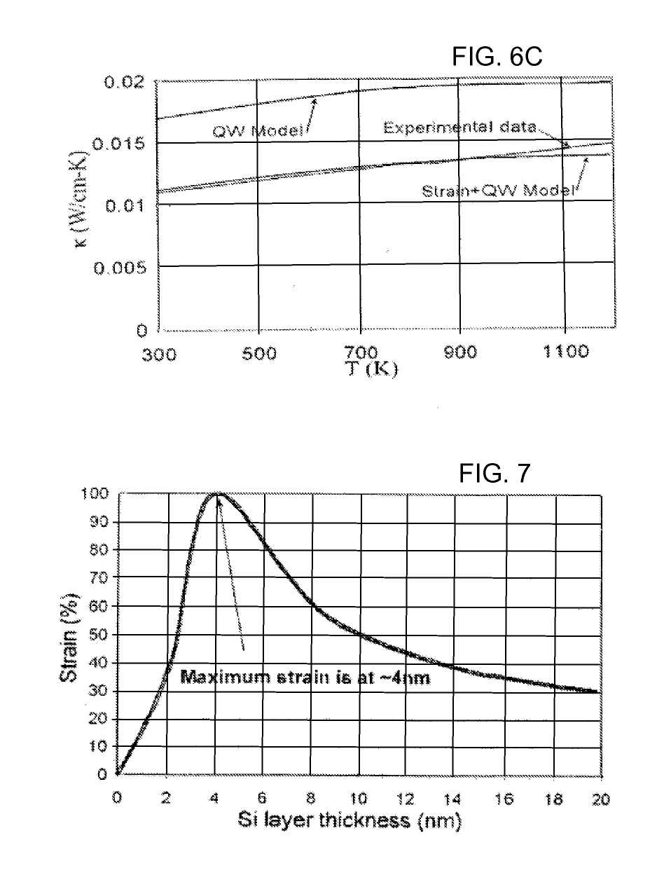

Applicants have performed calculations to estimate the effects of varying the quantity of quantum well material in the egg-crate described above. The results are shown in FIG. 6. In FIG. 6 five types (Types 1 through 5) of egg-crate design specifications are shown each with a different number of quantum well films per leg. In each case the films or film was the film described in the preferred egg-crate embodiment described above, namely an 8 micron quantum well layer of 400 periods of silicon and silicon-germanium layers on a 200 micron Kapton substrate. The preferred embodiment is Type 3 with 12 films. Type 1 has 46 of the quantum well film, Type 2 has 24 quantum well films, Type 4 has 6 quantum well films and Type 5 has only one quantum well film. Estimated maximum efficiency varied from 24.9 percent for the module with 46 films to 7.43 percent for the module with only one film. The efficiency of the preferred embodiment is estimated at 21.4 percent. As shown above the fabrication cost of the modules of the preferred embodiments is expected to be roughly proportional to the quantity of quantum well material used in the modules. With this assumption increasing the module maximum efficiency for 21.4 percent to 24.9 percent is expected to increase the module cost by about 300 to 400 percent. Reducing the quantity of quantum well material below 12 films per leg would reduce the cost but the efficiency drops off as a result and with only a few films per leg the module costs other than the film will reduce the potential cost savings.

### Performance Calculations

The calculations showing how the performance of the preferred embodiment was calculated and the assumptions that went into the calculations are shown below.

```
Material Properties
  Thermal Conductivity (k)
  $\begin{matrix}QW = 0.11 W \text{/} ( cmK ) \\ Kapton = 0.0014 W \text{/} ( cmK ) \\ Eggcrate material = 0.001 W \text{/} ( cmK )\end{matrix}$
  Seebeck Coefficient (α)
    $\begin{matrix}N leg = - 1.14 mV \text{/} K \\ P leg = 1.14 mV \text{/} K\end{matrix}$
  Resistivity (ρ)
    $\begin{matrix}N leg = 1 m Ω cm \\ P leg = 1 m Ω cm\end{matrix}$
QW film
  Substrate is 200 μm thick Kapton
  QW film is 8 μm thick
  Total film (with substrate) thickness = 200 μm + 8 μm = 208 μm
Spacer between QW films (also acts as an adhesive layer)
  200 μm thick Kapton
Leg
  Leg size = 3 mm × 5 mm × 4.9 mm
  Leg in 4.9 mm dimension consists of:
    12 layers of QW film
    12 layers of spacer material
      12(0.208 + 0.200) = 4.9 mm thick
  Volume of quantum well material in one leg
    12(0.0008 cm × 0.3 cm × 0.5 cm) = 0.00144 cm³
Module
  Legs in one module = 10 × 10 = 100
  Volume of quantum well material in one module
    100 × 0.00144 = 0.144 cm³
$\begin{matrix}area of module = 5.55 cm \times 5.55 cm \\ = 30.8 {cm}^{2}\end{matrix}$
Operating Conditions
    $\begin{matrix}Hot side temperature = 623 ° K . \\ Cold side temperature = 323 ° K . \\ Δ T = 300 ° K . \\ Tavg = 473 ° K .\end{matrix}$
Voltage Calculations
  $\begin{matrix}Leg & \begin{matrix}V = α Δ T \\ = 1.14 \times 300 \\ = 342 mV\end{matrix} \\ Module & \begin{matrix}V = 100 ( 0.342 ) \\ = 34.2 volts ( open circuit )\end{matrix}\end{matrix}$
Resistance Calculations
  $\begin{matrix}Film & \begin{matrix}area = 0.0008 cm \times 0.5 cm \\ = 0.0004 {cm}^{2} \\ length = 0.3 cm \\ R = ρ l \text{/} A \\ = 1 \times 0.3 \text{/} 0.0004 \\ = 750 Ω\end{matrix} \\ Leg & \begin{matrix}1 \text{/} {R}_{t} = 1 \text{/} {R}_{1} + 1 \text{/} {R}_{2} + … + 1 \text{/} {R}_{12} \\ = 12 ( 1 \text{/} 750 ) \\ = 0.016 m {Ω}^{- 1} \\ {R}_{t} = 1 \text{/} 0.16 \\ = 62.5 m Ω\end{matrix} \\ Module & \begin{matrix} R = 100 \times 0.0625 \\ = 6.25 Ω\end{matrix}\end{matrix}$
Thermal Calculations
  Lattice Thermal Conduction
  $\begin{matrix}Film & \begin{matrix} Q = kA Δ T \text{/} 1 \\ = 0.11 \times 0.0004 \times 300 \text{/} 0.3 \\ = 0.044 Watts\end{matrix} \\ Substrate & \begin{matrix}A = 0.02 \times 0.5 \\ = 0.01 {cm}^{2} \\ Q = 0.0014 \times 0.01 \times 300 \text{/} 0.3 \\ = 0.014 Watts\end{matrix} \\ Spacer & \begin{matrix}A = 0.02 \times 0.5 \\ = 0.01 {cm}^{2} \\ Q = 0.0014 \times 0.01 \times 300 \text{/} 0.3 \\ = 0.014 Watts\end{matrix} \\ Leg & \begin{matrix} Q = 12 ( Qleg + Qsubstrate + Qspacer ) \\ = 12 ( 0.044 + 0.014 + 0.014 ) \\ = 0.864 Watts\end{matrix} \\ Module & \begin{matrix}Q = 100 \times 0.864 \\ = 86.4 watts\end{matrix} \end{matrix}$
  Seebeck Heat
  $\begin{matrix}Leg & \begin{matrix}I = V \text{/} ( 2 R ) \\ = 34.2 \text{/} ( 2 \times 6.25 ) \\ = 2.74 amps \\ Q = α {T}_{h} I \\ = 0.00114 \times 623 \times 2.74 \\ = 1.95 watts\end{matrix} \\ Module & \begin{matrix}Q = 100 \times 1.95 \\ = 195 watts\end{matrix} \end{matrix}$
  Joule
  $\begin{matrix}Module & \begin{matrix}Q = VI \text{/} 4 \\ = 34.2 \times 2.74 \text{/} 4 \\ = 23.4 watts\end{matrix} \\ Eggcrate & \begin{matrix}A = 0.053 {cm}^{2} \\ L = 0.7 cm \\ Q = 0.01 \times 0.053 \times 300 \text{/} 0.7 \\ = 0.23 watts\end{matrix}\end{matrix}$
  Total Q through module
  $\begin{matrix}Q = {Q}_{lattice} + {Q}_{Seebeck} - {Q}_{Joule} + {Q}_{Eggcrate} \\ = 86.4 + 195 - 23.4 + 0.23 \\ = 258 watts\end{matrix}$
Module Properties
  $\begin{matrix}V = 34.2 volts ( open circuit ) \\ V = 17.1 volts ( at matched load ) \\ I = 2.74 amps ( at matched load ) \\ Ri = 6.25 Ω \\ P = V \times I \\ = 46.8 watts \\ Q = 258 watts \\ Efficiency = P \text{/} Q ( maximum efficiency happens at 39.3 watts ) \\ = 39.3 \text{/} 183 \\ = 21.4 \% \\ Heat flux = 258 \text{/} 30.8 \\ = 8.4 W \text{/} {cm}^{2} \\ Heat flux in film = 258 \text{/} 100 \text{/} 12 \text{/} ( .0008 \times 0.5 ) \\ = 538 W \text{/} {cm}^{2}\end{matrix}$
```

In summary the Seebeck coefficient of these films has been measured repeatedly by Applicants and is in the range of about 1.14 mV/K. The open circuit voltage per leg is the product of the Seebeck coefficient and the temperature difference (assumed to be 300 C). The film resistance is estimated to be 0.750 ohms. The film resistance per leg is 1/12 of that at 0.0625 ohms and the module resistance is 100 times that or 6.25 ohms. The heat flow through the module is estimated based on known thermal conductivity of the module materials and the result for the preferred egg-crate module is 258 watts. Estimated current at maximum power is estimated by assuming that the operating voltage will be ½ the open circuit voltage and that all of the current will flow through the quantum well film. The operating current is then obtained by dividing the operating voltage by the module “film” resistance and the electric power produced by the module is estimated to be the product of the operating current and the operating voltage or 46.8 watts. The total power flowing through the module in watts is the sum of the electric power plus the heat flow in watts through all of the components of the module which is estimated to be 258 watts. The efficiency of the module is the electric power divided by the total power flowing through the module which is estimated to be 21.4 percent.

### Strain in the Si/SiGe Films

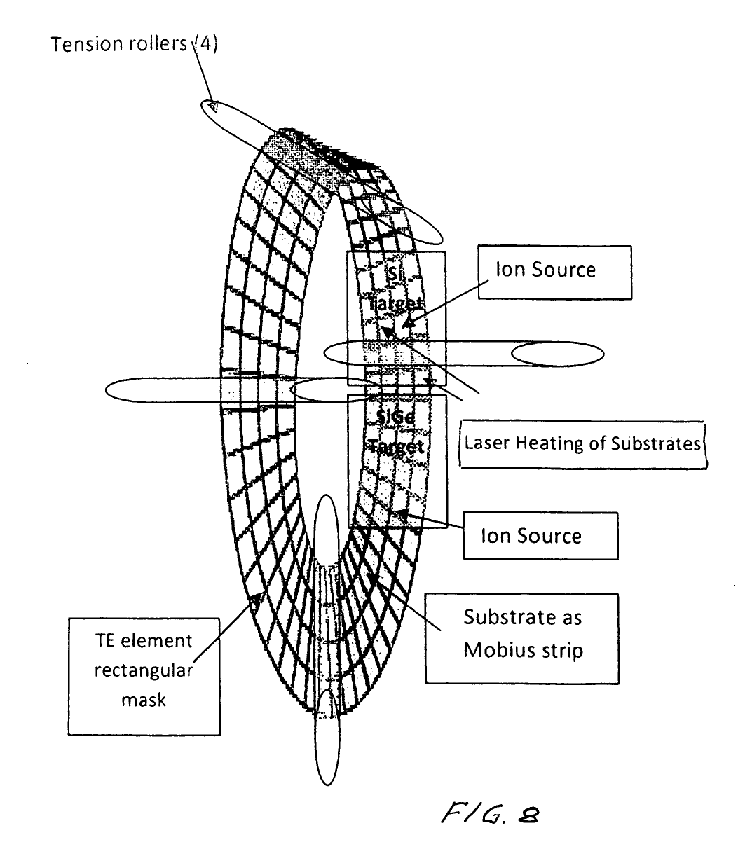

Strain in Applicants' quantum well Si/SiGe films increases the ZT, mostly through an increase in the Seebeck coefficient. FIGS. 6A, 6B and 6C show calculated versus experimental thermoelectric properties as a function of temperature for Applicants' Si/SiGe films. The model is Physics based and calculated using super computer facilities of the University of California at San Diego. The calculated quantum well plus strain model closely matches the experimental data. This excellent match between the analytical and experimental data underscores the viability of the model for describing the Si/SiGe films properties and behavior. The Physics model indicates that the Seebeck coefficient for these films is approximately proportional to the strain in the quantum well films. The strain model indicates that the strain could be increased by making the Si layer in the Si/SiGe thinner. FIG. 7 shows the calculated strain in the SiGe layer. The maximum strain could be attained at about 4 nm. Therefore, the thermoelectric performance at 4 nm should be about two times better than the performance at 10 nm.

### Substrates for Super-lattice Thermoelectric Material

As described in U.S. Pat. Nos. '467, '387, '964 and '965, quantum well thermoelectric material is preferably deposited in layers on substrates. For a typical substrate as described in those patents, heat loss through the substrate can greatly reduce the efficiency of a thermoelectric device made from the material. If the substrate is removed some of the thermoelectric layers could be damaged and even if not damaged the process of removal of the substrate could significantly increase the cost of fabrication of the devices. The present invention provides a substrate that can be retained. The substrate preferably should have a low thermal and electrical conductivity with good thermal stability and strong and flexible.

### Kapton®

Kapton is a product of DuPont Corporation. According to DuPont bulletins:

Kapton® polyimide film possesses a unique combination of properties that make it ideal for a variety of applications in many different industries. The ability of Kapton® to maintained its excellent physical, electrical, and mechanical properties over a wide temperature range has opened new design and application areas to plastic films.

Kapton® is synthesized by polymerizing an aromatic dianhydride and an aromatic diamine. It has excellent chemical resistance; there are no known organic solvents for the film. Kapton® does not melt or burn as it has the highest UL-94 flammability rating: V-0. The outstanding properties of Kapton® permit it to be used at both high and low temperature extremes where other organic polymeric materials would not be functional.

Adhesives are available for bonding Kapton® to itself and to metals, various paper types, and other films.

Kapton® polyimide film can be used in a variety of electrical and electronic insulation applications: wire and cable tapes, formed coil insulation, substrates for flexible printed circuits, motor slot liners, magnet wired insulation, transformer and capacitor insulation, magnetic and pressure-sensitive tapes, and tubing. Many of these applications are based on the excellent balance of electrical, thermal, mechanical, physical, and chemical properties of Kapton® over a wide range of temperatures. It is this combination of useful properties at temperature extremes that makes Kapton® a unique industrial material.

### Kapton® Substrate

Applicants have demonstrated that Kapton can be useful as a substrate film for super-lattice thermoelectric layers when high temperature (i.e. greater than 350 C) use is not planned. Applicants have shown that an amorphous silicon layer laid down with short crystalline range orders between the Kapton® substrate and the series of very thin conducting and barrier layers greatly improve thermoelectric performance especially for n-type layers. The preferred technique is to lay it on about 100 nm thick in an amorphous form then to at least partially crystallize it by heating the substrate and the silicon layer to about 350° C. to 375° C. When Kapton® is used as a substrate it can be mounted on a crystalline base that can be sand blasted off of the Kapton® after the thermoelectric film is deposited.

### Silicon

Silicon is a potential substrate material, but its thermal conductivity is much greater than Kapton. Si has also been used by Applicants as a substrate for depositing Si/SiGe alloys. Si is available commercially in films as thin as 5 microns from suppliers such as Virginia Semiconductor with offices in Fredricksburg, Va. The silicon film is stable at much higher temperatures than Kapton. Silicon film may be attractive in some applications especially very high temperature applications especially if it can be obtained in extremely thin sheets. Also Applicants have experimented with porous silicon which has very low thermal conductivity properties as compared to silicon. If the pores beginning on one side of the film can be controlled to within a micron or less from the other surface, the porous silicon film could make a very good substrate material. Alternatively the entire substrate could be removed by etching the Silicon to the point where the quantum well layers begin. In this case it may be necessary to bond the quantum well films to Kapton or glass with a low thermal conductivity to provide structural support to the films.

### Other Substrates

Many other organic materials such as Mylar, polyethylene, NaCl and polyamide, polyamide-imides and polyimide compounds could be used as substrates. Other potential substrate materials are oxide films such as SiO₂, Al₂O₃ and TiO₂. Mica could also be used for a substrate. As stated above, the substrate preferably should be very thin and a very good thermal and electrical insulator with good thermal stability, strong and flexible. At very high temperatures substrates glass or ceramics with low electric and thermal conductivity could be used.

### Double Side Coating of Kapton Film

It is possible to deposit the n and p materials at the same times on opposite sides of the substrate. One technique is to coat one side of the Kapton as explained above then remove the film and coat the other side. Another technique is to arrange the film on a web coater as a continuous Mobius strip so that both sides can be coated at the same time without removing the film.

The advantage of this process is to balance out the stresses that are developed as the films are deposited and also the stresses the form by the differences between the thermal expansion of the SiGe alloys and the high thermal expansion of Kapton or the low thermal expansion of Si. Also, the cost of the sputtering operation is reduced. Samples can also be prepared with the coatings separately deposited. Such samples were able to endure excellent adhesion when rolled up in the reverse direction so the second deposition could be performed.

### Test Results

In the web coating demonstration performed by Applications as described above, p-type samples with 50 layers of Si_{0.8}Ge_{0.2} and 50 layers of Si were fabricated in the web coater. The source power supply for each target was set at 15 kHz and an off power pulse width of 2.2 μsec. The source power for the pulse DC power source was 3 kW and a web coater belt speed of 2.5 ft/min for Si deposition giving 9-nm layers of Si and the alternate Si_{0.8}Ge_{0.2} layers were with the pulse DC source power at 3 kW and web coater belt speed of 3.6 ft/min giving a 9-nm thickness of Si_{0.8}Ge_{0.2}. The total film thickness was measured by scanning electron microscope (SEM) and produced near uniform film along 2 ft long sections. The measurements are: 0.540 μm, 0.555 μm, 0.576 μm, 0.544 μm, 0.559 μm, 0.580 μm, 0.549 μm, 0.527 μm, 0.518 μm, 0.501 μm where the expected thickness was 0.55 μm±0.05 μm so all measurements are acceptable for quantum well film performance.

### Need for Crystalline Superlattice Legs

Applicants tests and theoretical studies have shown that there is a strong correlation between the crystalinity of the superlattice legs and the thermoelectric properties. Their studies show that if the semiconductor material in the legs is amorphous there is no significant improvement in the thermoelectric properties. If the legs are near perfect crystals the thermoelectric properties are greatly enhanced. There tests and studies however further suggests that the substantial improvement in performance is between amorphous and about 30 percent crystalline and in that range the performance seems to be approximately linear. Then there is little or no improvement between 30 percent crystalline and 100 percent crystalline. The net conclusion of these studies is that it is important that procedures for the production of the quantum well materials be designed to produce at least 30 percent crystalline semiconductor thermoelectric material and that perfect crystallinity in not necessary.

### Other Egg-Crate Designs

Persons skilled in the thermoelectric art will recognize that many other egg-crate designs are possible that will provide the advantages of the thermoelectric egg-crate which include the electrical isolation of the legs except where they need to be connected and to permit the electrical connections to be simply sprayed onto the hot and cold surfaces of the module. Many sizes are possible. The number of legs could be tailored as desired. Series and parallel connections can be easily designed into the modules.

### Egg-Crate with Wide Thin Legs

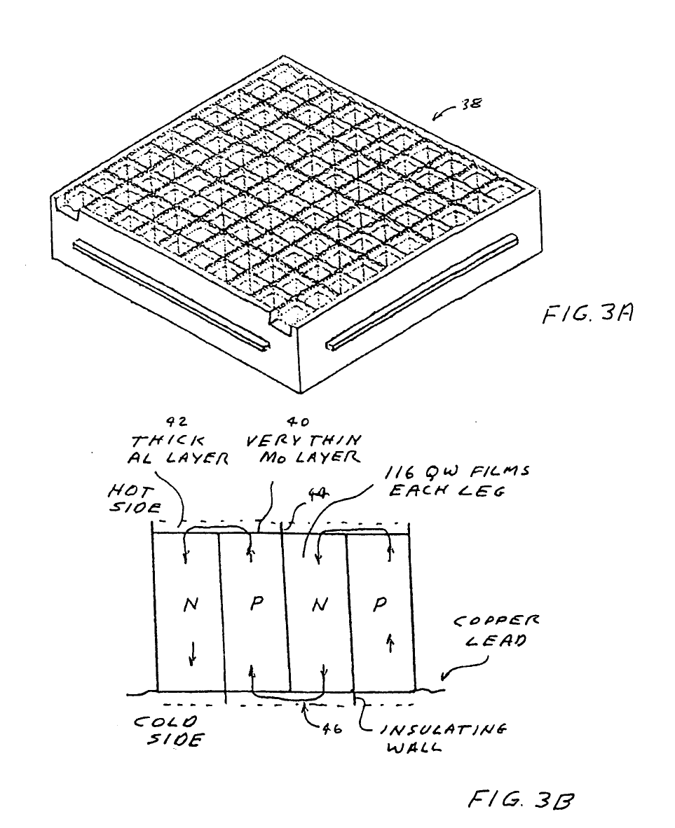

A preferred embodiment easily adapted for use with these quantum well film is a one-dimensional egg-crate as compared to the two-dimensional 10×10 egg-crate described above and shown in FIG. 3A. In a preferred one-dimensional egg-crate embodiment the quantum well film and spacer stack as shown in FIG. 4C is only 0.816 mm high (i.e. only two layers of the 208 micron quantum well film and two layers of spacers for a total thickness of 0.816 mm). The stack is sliced and diced into 100 quantum well legs which have dimensions of 0.816 mm×5 cm×3 cm. An egg-crate is provided with leg spaces a little larger than the quantum well legs. The walls of the egg-crate are designed so that when electrical contacts are sprayed on as described in U.S. Pat. No. 8,856,201, all of the legs will be electrically isolated from each other except where they are connected in series at the hot and cold sides on the module.

### Other Lattice Materials

Many other thermoelectric materials may be used as p-legs along with Si/SiGe or Si/SiC n-legs. Super-lattice materials are preferred. Measurements of thermal conductivity normally show a threefold reduction in QW films compared with bulk materials, as reported below.

### Substrates with QW Film on Both Sides

There are some advantages in coating the substrates on both sides. This could be done by coating one side as described above then turning the film over and coating the other side. Forming the substrate film into a Mobius strip would permit an appropriately designed web coater to coat both sides as the film passes the deposition chambers. FIG. 8 shows a flexible substrate configured as a Mobius strip to allow continuous deposition without reciprocal motion and coating of both sides of film after only one pass over the target and target nearly eliminating stresses on both sides of the film. Tension and bow rollers keep films in tension for axial and perpendicular to axial directions. Laser annealing and ion assisted deposition prior to deposition, during deposition and post deposition is provided by ion sources.

While the above description contains many specificities, the reader should not construe these as limitations on the scope of the invention, but merely as exemplifications of preferred embodiments thereof. Those skilled in the art will envision many other possible variations within its scope. The preferred layer thickness is about 10 nm; however, layer thickness could be somewhat larger or smaller such as within the range of 20 nm down to about 5 nm. It is not necessary that the layers be grown on film. For example, they could be grown on thicker substrates that are later removed. There are many other ways to make the connections between the legs other than the methods discussed. Efficiency values referred to in this specification could were generally based on a delta T of about 200° C. Substantially higher efficiencies could be realized at higher delta T's. Accordingly, the reader is requested to determine the scope of the invention by the appended claims and their legal equivalents, and not by the examples which have been given.

We claim:

1. A low cost quantum well thermoelectric module comprising:
A) a plurality of quantum well n-legs, each n-leg in said plurality of n-legs comprising:
1) a plurality of quantum well films, each quantum well film in said plurality of quantum well film being comprised of a plurality of superlattice layers, having thicknesses of less than 20 nm, of n-type semiconductor material alternating with layers of electrically insulating materials,
2) a plurality of films comprised of electrical and thermal insulating material separating at least a portion of said quantum well films in said plurality of quantum well films from other quantum well films in said plurality of quantum well films,
wherein the quantum well film in each of the plurality of n-legs define a volume of quantum well film and the plurality of films of insulating material in each of the plurality of n-legs define a volume of insulating material and the ratio of the volume of insulating material to the volume of quantum well material is at least 12.
B) a plurality of quantum well p-legs, each p-leg in said plurality of p-legs comprising:
1) a plurality of quantum well films, each quantum well film in said plurality of quantum well film being comprised of a plurality of superlattice layers, having thicknesses of less than 20 nm, of p-type semiconductor material alternating with layers of electrically insulating materials,
2) a plurality of films comprised of electrical and thermal insulating material separating at least a portion of said quantum well films in said plurality of quantum well films from other quantum well films in said plurality of quantum well films,
wherein the quantum well film in each of the plurality of p-legs define a volume of quantum well film and the plurality of films of insulating material in each of the plurality of p-legs define a volume of insulating material and the ratio of the volume of insulating material to the volume of quantum well material is at least 12;
C) a plurality of electrical connector connecting said plurality of n-legs and p-legs in series.

2. The module as in claim 1 wherein the ratio of the volume of insulating material to the volume of quantum well material is at least 20.

3. The module as in claim 1 wherein the ratio of the volume of insulating material to the volume of quantum well material is at least 50.

4. The module as in claim 1 wherein the ratio of the volume of insulating material to the volume of quantum well material is at least 100.

5. The module as in claim 1 wherein the plurality of n-legs and p-legs are contained in a thermoelectric egg-crate.

6. The module as in claim 1 wherein each of the plurality of n-legs define a hot side and a cold side and both the hot side and cold side comprise implanted ions to improve electrical conductivity near the hot side and the cold side.

7. The module as in claim 1 wherein each of the plurality of p-legs define a hot side and a cold side and both the hot side and cold side comprise implanted ions to improve electrical conductivity near the hot side and the cold side.

8. The module as in claim 7 wherein the thicknesses of said superlattice layers is about 10 nm.

9. The module as in claim 7 wherein the thicknesses of said superlattice layers is about 4 nm.

10. The module as in claim 1 wherein the superlattice layers are layers deposited on a substrate film.

11. The module as in claim 10 wherein the substrate film is a polyimide film.

12. The module as in claim 10 wherein the substrate film is a material chosen form the following group of materials: Mylar, polyethylene, NaCl, polyamide, polyamide-imides, polyimide compounds, oxide film, mica.

13. The module as in claim 1 wherein the insulator material is in the form of substrate material and spacer material.

14. The module as in claim 13 wherein the substrate material and the spacer material is a polyimide.

15. A low cost process of making thermoelectric modules comprising the steps of:
A) loading at least 10 square meters of substrate film having a width of at least 10 cm on a web coating machine having at least two deposition chambers,
B) loading a portion of said at least two deposition chambers with an n-type semiconductor material and loading a portion of said at least two deposition chambers with an insulating semiconductor material,
C) depositing at least 100 alternating layers, having thicknesses no greater than about 20 nanometers, of said n-type and said insulating simi-conductor thermoelectric material on said substrate film to form a super-lattice layer on the substrate,
D) removing the coated n-type substrate film from the web coater and cut the film into separate sheets,
E) stacking the sheets to produce a stack of super lattice n-type thermoelectric films having a thickness of at least 1 millimeter.
F) cutting the stack a plurality of separate portion to form a plurality of n-type thermoelectric legs,
G) loading at least 10 square meter of substrate film having a width of at least 10 cm on a web coating machine having at least two deposition chamber,
H) loading a portion of said at least two deposition chambers with an p-type semiconductor material and loading a portion of said at least two deposition chambers with an insulating semiconductor material,
I) depositing at least 100 alternating layers, having thicknesses no greater than about 15 nanometers, of said p-type and said insulating semiconductor thermoelectric material on said substrate film to form a super-lattice layer on the substrate,
J) removing the coated p-type substrate film from the web coater and cut the film into separate sheets,
K) stacking the sheets to produce a stack of super lattice p-type thermoelectric films having a thickness of at least 1 millimeter.
L) cutting the stack a plurality of separate portion to form a plurality of p-type thermoelectric legs,
M) loading the n-legs and the p-legs in a thermoelectric egg-crate defining hot and cold surfaces and having partitions for electrically separating the legs from each other except at the two surfaces where the partitions are modified to allow desired connections between specific legs,
N) coating the hot and cold surfaces with at least one electrically conducting spray,
O) removing excess conducting material from both sides to expose the egg-crate partitions so as to electrically connect the legs.
P) attaching electrical leads to complete the quantum well thermoelectric module.
